(19) United States
(12) Patent Application Publication
(10) Pub. No.: US 2025/0323612 A1
(43) Pub. Date: Oct. 16, 2025

(54) CURRENT-DRIVEN LOOPBACK CALIBRATION

(71) Applicant: QUALCOMM Incorporated, San Diego, CA (US)

(72) Inventor: Sunyoung KIM, San Jose, CA (US)

(21) Appl. No.: 18/631,594

(22) Filed: Apr. 10, 2024

(51) Int. Cl. H03F 3/45; H04B 1/04

(52) U.S. Cl. CPC H03F 3/45475; H04B 1/0458; H04B 1/0475; H03F 2200/294; H03F 2200/451

(57) ABSTRACT

Certain aspects of the present disclosure generally relate to electronic devices and, more particularly, to techniques and apparatus for calibrating a transceiver. One example apparatus generally includes: a transmitter path including a first transmit amplifier; a receiver path including a transconductance amplifier; and a loopback calibration path coupled between an output of the first transmit amplifier and an output of the transconductance amplifier, wherein the loopback calibration path comprises a voltage-to-current converter.

### TECHNICAL FIELD

Certain aspects of the present disclosure generally relate to electronic devices and, more particularly, to techniques and apparatus for calibrating a transceiver.

### BACKGROUND

Wireless communication devices are widely deployed to provide various communication services such as telephony, video, data, messaging, broadcasts, and so on. Such wireless communication devices may transmit and/or receive radio frequency (RF) signals via any of various suitable radio access technologies (RATs) including, but not limited to, Fifth Generation (5G) New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., WiFi), and the like.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station. The base station and/or mobile station may include one or more transmit and receive paths that may be calibrated.

### SUMMARY

The systems, methods, and devices of the disclosure each have several aspects, no single one of which is solely responsible for its desirable attributes. Without limiting the scope of this disclosure as expressed by the claims that follow, some features will now be discussed briefly. After considering this discussion, and particularly after reading the section entitled “Detailed Description,” one will understand how the features of this disclosure provide the advantages described herein.

Certain aspects of the present disclosure are directed towards an apparatus for wireless communication. The apparatus generally includes: a transmitter path including a first transmit amplifier; a receiver path including a transconductance amplifier; and a loopback calibration path coupled between an output of the first transmit amplifier and an output of the transconductance amplifier, wherein the loopback calibration path comprises a voltage-to-current converter.

Certain aspects of the present disclosure are directed towards a method for wireless communication. The method generally includes: generating an amplified voltage via a transmit amplifier of a transmitter path; converting the amplified voltage to a current via a voltage-to-current converter of a loopback calibration path; providing the current to an output of a transconductance amplifier of a receiver path via the loopback calibration path; generating, via the receiver path, a processed signal based on the current; and calibrating the receiver path based on the processed signal.

Certain aspects of the present disclosure are directed towards a wireless device. The wireless device generally includes: at least one antenna; a transmitter path coupled to the at least one antenna and including a transmit amplifier; a receiver path coupled to the at least one antenna and including a transconductance amplifier; and a loopback calibration path coupled between an output of the transmit amplifier and an output of the transconductance amplifier, wherein the loopback calibration path comprises a voltage-to-current converter.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram conceptually illustrating a design of an example base station (BS) and user equipment (UE), in which aspects of the present disclosure may be practiced.

FIG. 3 is a block diagram of an example radio frequency (RF) transceiver, in which aspects of the present disclosure may be practiced.

FIG. 4 is a block diagram of an example wireless device with an RF transceiver circuit including a loopback calibration path, in accordance with certain aspects of the present disclosure.

FIG. 5 is a block diagram of an example wireless device with an RF transceiver circuit including a loopback calibration path implemented with voltage-to-current and current-to-voltage converters, in accordance with certain aspects of the present disclosure.

FIG. 6 is a block diagram of an example wireless device with an RF transceiver circuit including a loopback calibration path between an output of a driver amplifier (DA) and an output of a transconductance amplifier, in accordance with certain aspects of the present disclosure.

FIG. 7 is a flow diagram illustrating example operations for wireless communication, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed toward techniques for calibrating a transceiver using a loopback calibration path between a transmitter and a receiver. The loopback calibration path may be coupled between an output of an amplifier of the transmitter and an output of a transconductance amplifier of the receiver. The loopback calibration path may include a voltage-to-current (V-I) converter to convert an amplified voltage at the output of the amplifier to a current. The current is then provided to the receiver. The transmitter and receiver may be located far from each other to reduce the interference between the transmitter and the receiver. Therefore, the loopback calibration path may have a long trace. By converting the amplified voltage from the voltage domain to the current domain, current instead of voltage can be provided to the receiver on the long trace of the calibration path to avoid issues with voltage drop that might otherwise be present if the amplified voltage was provided to the receive path in the voltage domain. The current may be provided to an output of a transconductance amplifier of the receiver, avoiding the usage of a current-to-voltage (I-V) converter on the calibration path for converting the current back to a voltage, as described in more detail herein.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

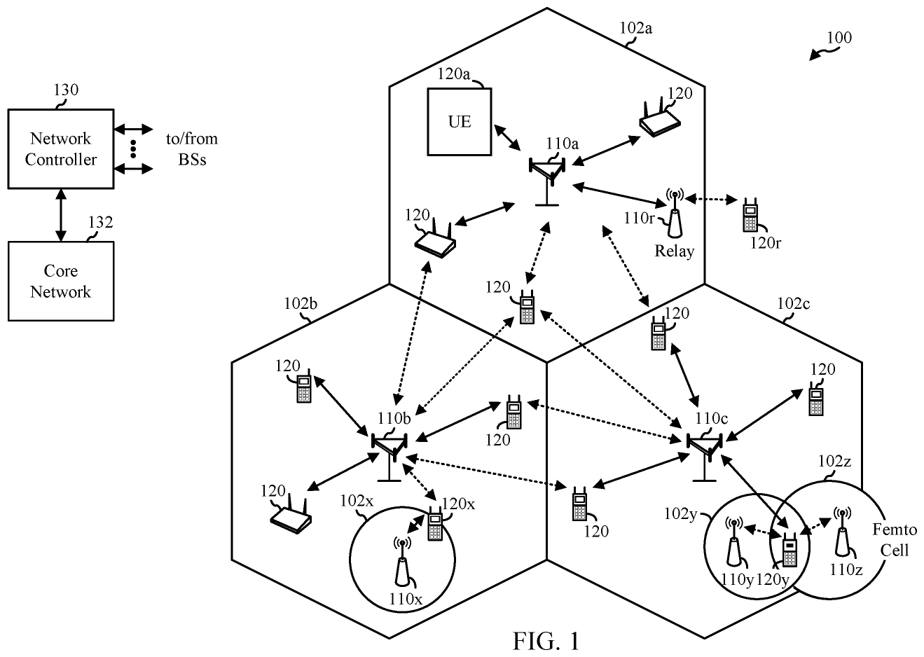

FIG. 1 illustrates an example wireless communications network 100, in which aspects of the present disclosure may be practiced. For example, the wireless communications network 100 may be a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation/Third Generation (2G/3G) network), or a code division multiple access (CDMA) system (e.g., a 2G/3G network), or may be configured for communications according to an IEEE standard such as one or more of the 802.11 standards, etc.

As illustrated in FIG. 1, the wireless communications network 100 may include a number of base stations (BSs) 110a-z (each also individually referred to herein as “BS 110” or collectively as “BSs 110”) and other network entities. A BS may also be referred to as an access point (AP), an evolved Node B (eNodeB or eNB), a next generation Node B (gNodeB or gNB), or some other terminology.

A BS 110 may provide communication coverage for a particular geographic area, sometimes referred to as a “cell,” which may be stationary or may move according to the location of a mobile BS. In some examples, the BSs 110 may be interconnected to one another and/or to one or more other BSs or network nodes (not shown) in wireless communications network 100 through various types of backhaul interfaces (e.g., a direct physical connection, a wireless connection, a virtual network, or the like) using any suitable transport network. In the example shown in FIG. 1, the BSs 110a, 110b, and 110c may be macro BSs for the macro cells 102a, 102b, and 102c, respectively. The BS 110x may be a pico BS for a pico cell 102x. The BSs 110y and 110z may be femto BSs for the femto cells 102y and 102z, respectively. A BS may support one or multiple cells.

The BSs 110 communicate with one or more user equipment's (UEs) 120a-y (each also individually referred to herein as “UE 120” or collectively as “UEs 120”) in the wireless communications network 100. A UE may be fixed or mobile and may also be referred to as a user terminal (UT), a mobile station (MS), an access terminal, a station (STA), a client, a wireless device, a mobile device, or some other terminology. A user terminal may be a wireless device, such as a cellular phone, a smartphone, a personal digital assistant (PDA), a handheld device, a wearable device, a wireless modem, a laptop computer, a tablet, a personal computer, etc.

The BSs 110 are considered transmitting entities for the downlink and receiving entities for the uplink. The UEs 120 are considered transmitting entities for the uplink and receiving entities for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink. Nᵤₚ UEs may be selected for simultaneous transmission on the uplink, Nan UEs may be selected for simultaneous transmission on the downlink. Nᵤₚ may or may not be equal to N_{dn}, and Nᵤₚ and N_{dn} may be static values or can change for each scheduling interval. Beam-steering or some other spatial processing technique may be used at the BSs 110 and/or UEs 120.

The UEs 120 (e.g., 120x, 120y, etc.) may be dispersed throughout the wireless communications network 100, and each UE 120 may be stationary or mobile. The wireless communications network 100 may also include relay stations (e.g., relay station 110r), also referred to as relays or the like, that receive a transmission of data and/or other information from an upstream station (e.g., a BS 110a or a UE 120r) and send a transmission of the data and/or other information to a downstream station (e.g., a UE 120 or a BS 110), or that relays transmissions between UEs 120, to facilitate communication between devices.

The BSs 110 may communicate with one or more UEs 120 at any given moment on the downlink and uplink. The downlink (i.e., forward link) is the communication link from the BSs 110 to the UEs 120, and the uplink (i.e., reverse link) is the communication link from the UEs 120 to the BSs 110. A UE 120 may also communicate peer-to-peer with another UE 120.

The wireless communications network 100 may use multiple transmit and multiple receive antennas for data transmission on the downlink and uplink. BSs 110 may be equipped with a number Nap of antennas to achieve transmit diversity for downlink transmissions and/or receive diversity for uplink transmissions. A set Nu of UEs 120 may receive downlink transmissions and transmit uplink transmissions. Each UE 120 may transmit user-specific data to and/or receive user-specific data from the BSs 110. In general, each UE 120 may be equipped with one or multiple antennas. The Nu UEs 120 can have the same or different numbers of antennas.

The wireless communications network 100 may be a time division duplex (TDD) system or a frequency division duplex (FDD) system. For a TDD system, the downlink and uplink share the same frequency band. For an FDD system, the downlink and uplink use different frequency bands. The wireless communications network 100 may also utilize a single carrier or multiple carriers for transmission. Each UE 120 may be equipped with a single antenna (e.g., to keep costs down) or multiple antennas (e.g., where the additional cost can be supported).

A network controller 130 (also sometimes referred to as a “system controller”) may be in communication with a set of BSs 110 and provide coordination and control for these BSs 110 (e.g., via a backhaul). In certain cases (e.g., in a 5G NR system), the network controller 130 may include a centralized unit (CU) and/or a distributed unit (DU). In certain aspects, the network controller 130 may be in communication with a core network 132 (e.g., a 5G Core Network (5GC)), which provides various network functions such as Access and Mobility Management, Session Management, User Plane Function, Policy Control Function, Authentication Server Function, Unified Data Management, Application Function, Network Exposure Function, Network Repository Function, Network Slice Selection Function, etc.

In certain aspects of the present disclosure, the BSs 110 and/or the UEs 120 may include a loopback calibration path coupled between a transmitter path and an output of a transconductance amplifier of a receiver path, as described in more detail herein.

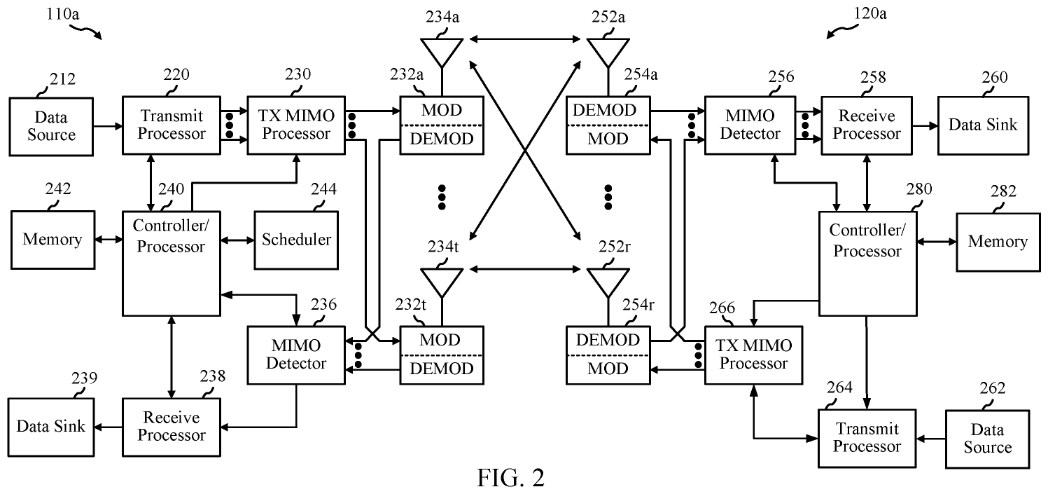

FIG. 2 illustrates example components of BS 110a and UE 120a (e.g., from the wireless communications network 100 of FIG. 1), in which aspects of the present disclosure may be implemented.

On the downlink, at the BS 110a, a transmit processor 220 may receive data from a data source 212, control information from a controller/processor 240, and/or possibly other data (e.g., from a scheduler 244). The various types of data may be sent on different transport channels. For example, the control information may be designated for the physical broadcast channel (PBCH), physical control format indicator channel (PCFICH), physical hybrid automatic repeat request (HARQ) indicator channel (PHICH), physical downlink control channel (PDCCH), group common PDCCH (GC PDCCH), etc. The data may be designated for the physical downlink shared channel (PDSCH), etc. A medium access control (MAC)-control element (MAC-CE) is a MAC layer communication structure that may be used for control command exchange between wireless nodes. The MAC-CE may be carried in a shared channel such as a PDSCH, a physical uplink shared channel (PUSCH), or a physical sidelink shared channel (PSSCH).

The processor 220 may process (e.g., encode and symbol map) the data and control information to obtain data symbols and control symbols, respectively. The transmit processor 220 may also generate reference symbols, such as for the primary synchronization signal (PSS), secondary synchronization signal (SSS), PBCH demodulation reference signal (DMRS), and channel state information reference signal (CSI-RS).

A transmit (TX) multiple-input, multiple-output (MIMO) processor 230 may perform spatial processing (e.g., precoding) on the data symbols, the control symbols, and/or the reference symbols, if applicable, and may provide output symbol streams to the modulators (MODs) in transceivers 232a-232t. Each modulator in transceivers 232a-232t may process a respective output symbol stream (e.g., for orthogonal frequency division multiplexing (OFDM), etc.) to obtain an output sample stream. Each of the transceivers 232a-232t may further process (e.g., convert to analog, amplify, filter, and upconvert) the output sample stream to obtain a downlink signal. Downlink signals from the transceivers 232a-232t may be transmitted via the antennas 234a-234t, respectively.

At the UE 120a, the antennas 252a-252r may receive the downlink signals from the BS 110a and may provide received signals to the transceivers 254a-254r, respectively. The transceivers 254a-254r may condition (e.g., filter, amplify, downconvert, and digitize) a respective received signal to obtain input samples. Each demodulator (DEMOD) in the transceivers 232a-232t may further process the input samples (e.g., for OFDM, etc.) to obtain received symbols. A MIMO detector 256 may obtain received symbols from all the demodulators in transceivers 254a-254r, perform MIMO detection on the received symbols if applicable, and provide detected symbols. A receive processor 258 may process (e.g., demodulate, deinterleave, and decode) the detected symbols, provide decoded data for the UE 120a to a data sink 260, and provide decoded control information to a controller/processor 280.

On the uplink, at UE 120a, a transmit processor 264 may receive and process data (e.g., for the physical uplink shared channel (PUSCH)) from a data source 262 and control information (e.g., for the physical uplink control channel (PUCCH)) from the controller/processor 280. The transmit processor 264 may also generate reference symbols for a reference signal (e.g., the sounding reference signal (SRS)). The symbols from the transmit processor 264 may be precoded by a TX MIMO processor 266 if applicable, further processed by the modulators (MODs) in transceivers 254a-254r (e.g., for single-carrier frequency division multiplexing (SC-FDM), etc.), and transmitted to the BS 110a. At the BS 110a, the uplink signals from the UE 120a may be received by the antennas 234, processed by the demodulators in transceivers 232a-232t, detected by a MIMO detector 236 if applicable, and further processed by a receive processor 238 to obtain decoded data and control information sent by the UE 120a. The receive processor 238 may provide the decoded data to a data sink 239 and the decoded control information to the controller/processor 240.

The memories 242 and 282 may store data and program codes for BS 110a and UE 120a, respectively. The memories 242 and 282 may also interface with the controllers/processors 240 and 280, respectively. A scheduler 244 may schedule UEs for data transmission on the downlink and/or uplink.

In certain aspects of the present disclosure, the transceivers 232 and/or the transceivers 254 may include a loopback calibration path coupled between a transmitter path and an output of a transconductance amplifier of a receiver path, as described in more detail herein.

NR may utilize orthogonal frequency division multiplexing (OFDM) with a cyclic prefix (CP) on the uplink and downlink. NR may support half-duplex operation using time division duplexing (TDD). OFDM and single-carrier frequency division multiplexing (SC-FDM) partition the system bandwidth into multiple orthogonal subcarriers, which are also commonly referred to as tones, bins, etc. Each subcarrier may be modulated with data. Modulation symbols may be sent in the frequency domain with OFDM and in the time domain with SC-FDM. The spacing between adjacent subcarriers may be fixed, and the total number of subcarriers may be dependent on the system bandwidth. The system bandwidth may also be partitioned into subbands. For example, a subband may cover multiple resource blocks (RBs).

### Example RF Transceiver

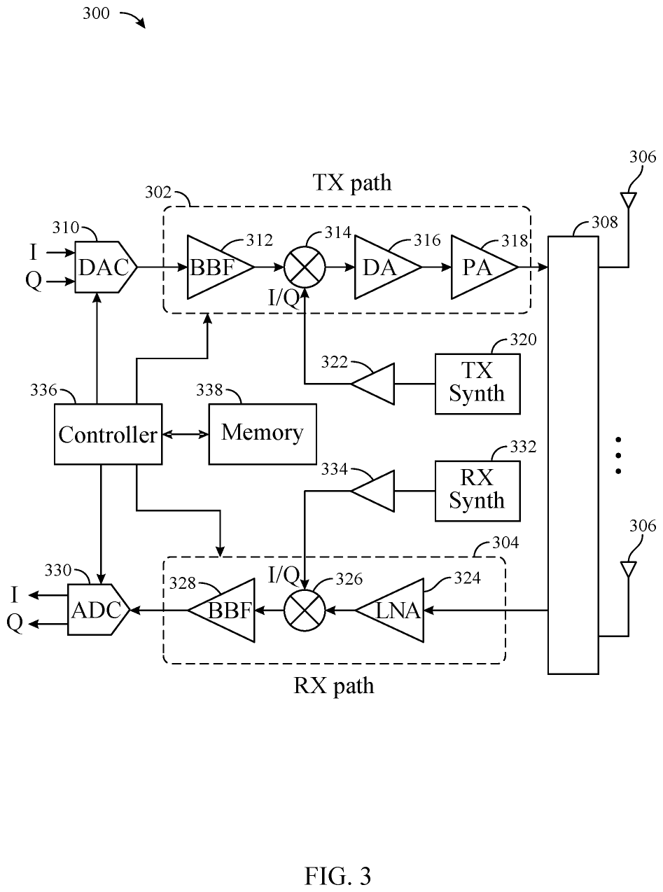

FIG. 3 is a block diagram of an example radio frequency (RF) transceiver circuit 300, in accordance with certain aspects of the present disclosure. The RF transceiver circuit 300 includes at least one transmit (TX) path 302 (also known as a “transmit chain”) for transmitting signals via one or more antennas 306 and at least one receive (RX) path 304 (also known as a “receive chain”) for receiving signals via the antennas 306. When the TX path 302 and the RX path 304 share an antenna 306, the paths may be connected with the antenna via an interface 308, which may include any of various suitable RF devices, such as a switch, a duplexer, a diplexer, a multiplexer, and the like.

Receiving in-phase (I) and/or quadrature (Q) baseband analog signals from a digital-to-analog converter (DAC) 310, the TX path 302 may include a baseband filter (BBF) 312, a mixer 314, a driver amplifier (DA) 316, and a power amplifier (PA) 318. The BBF 312, the mixer 314, the DA 316, and the PA 318 may be included in a radio frequency integrated circuit (RFIC). For certain aspects, the PA 318 may be external to the RFIC.

The BBF 312 filters the baseband signals received from the DAC 310, and the mixer 314 mixes the filtered baseband signals with a transmit local oscillator (LO) signal to convert the baseband signal of interest to a different frequency (e.g., upconvert from baseband to a radio frequency). This frequency-conversion process produces the sum and difference frequencies between the LO frequency and the frequencies of the baseband signal of interest. The sum and difference frequencies are referred to as the “beat frequencies.” The beat frequencies are typically in the RF range, such that the signals output by the mixer 314 are typically RF signals, which may be amplified by the DA 316 and/or by the PA 318 before transmission by the antenna(s) 306. While one mixer 314 is illustrated, several mixers may be used to upconvert the filtered baseband signals to one or more intermediate frequencies and to thereafter upconvert the intermediate frequency (IF) signals to a frequency for transmission.

The RX path 304 may include a low noise amplifier (LNA) 324, a mixer 326, and a baseband filter (BBF) 328. In some aspects, the LNA may be implemented with pre-biasing during a bypass mode. The LNA 324, the mixer 326, and the BBF 328 may be included in one or more RFICs, which may or may not be the same RFIC that includes the TX path components. RF signals received via the antenna(s) 306 may be amplified by the LNA 324, and the mixer 326 mixes the amplified RF signals with a receive local oscillator (LO) signal to convert the RF signal of interest to a different baseband frequency (e.g., downconvert). The baseband signals output by the mixer 326 may be filtered by the BBF 328 before being converted by an analog-to-digital converter (ADC) 330 to digital I and/or Q signals for digital signal processing.

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO may be produced by a TX frequency synthesizer 320, which may be buffered or amplified by amplifier 322 before being mixed with the baseband signals in the mixer 314. Similarly, the receive LO may be produced by an RX frequency synthesizer 332, which may be buffered or amplified by amplifier 334 before being mixed with the RF signals in the mixer 326. For certain aspects, a single frequency synthesizer may be used for both the TX path 302 and the RX path 304. In certain aspects, the TX frequency synthesizer 320 and/or RX frequency synthesizer 332 may include a frequency divider/multiplier that is driven by an oscillator (e.g., a VCO) in the frequency synthesizer.

A controller 336 (e.g., controller/processor 280 in FIG. 2) may direct the operation of the RF transceiver circuit 300A, such as transmitting signals via the TX path 302 and/or receiving signals via the RX path 304. The controller 336 may be a processor, a digital signal processor (DSP), an application-specific integrated circuit (ASIC), a field-programmable gate array (FPGA) or other programmable logic device (PLD), discrete gate or transistor logic, discrete hardware components, or any combination thereof. A memory 338 (e.g., memory 282 in FIG. 2) may store data and/or program codes for operating the RF transceiver circuit 300. The controller 336 and/or the memory 338 may include control logic (e.g., complementary metal-oxide-semiconductor (CMOS) logic).

In some aspects, the RF transceiver circuit 300 may include a loopback calibration path coupled between a transmitter path (e.g. TX path 302) and an output of a transconductance amplifier of a receiver path (e.g., RX path 304), as described in more detail herein.

While FIGS. 1-3 provide wireless communications as an example application in which certain aspects of the present disclosure may be implemented to facilitate understanding, certain aspects described herein may be used for any of various other suitable systems.

### Example Techniques for Transceiver Calibration

Modern receiver architectures use a quadrature modulation technique where a receiver baseband output includes an in-phase (I) path and a quadrature (Q) path. Ideally, there should be no gain difference between the paths and a 90° phase difference between the paths. However, the two paths may have a certain gain difference, and/or the phase difference may not be 90°. Therefore, internal calibration may be used. The calibration may involve using a loopback calibration path between a transmitter path and a receiver path of the wireless device, enabling a reduction in the gain difference and achieving a 90° phase (or close to a 90° phase) difference between the receiver I-path and the receiver Q-path. For instance, a signal may be sent from the transmitter path to the receiver path using the loop calibration path. The signal is then processed by the receiver path (e.g., downconverted via a mixer, filtered, and converted to the digital domain via an analog-to-digital converter (ADC)), measured in the digital domain, and used for calibrating the I and Q paths.

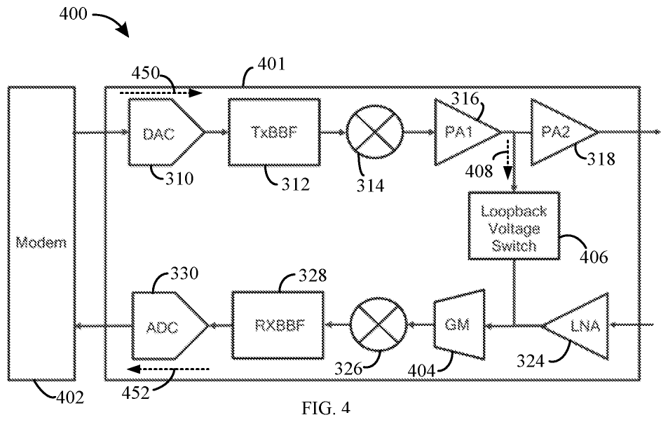

FIG. 4 is an example wireless device 400 with an RF transceiver circuit 401 including a loopback calibration path, in accordance with certain aspects of the present disclosure. A digital signal from a controller 402 (e.g., modem) may be converted from a digital domain to an analog domain via a digital-to-analog converter (DAC) 310 of the transmitter path 450 to generate an analog signal that is filtered via baseband filter (BBF) 312 of the transmitter path 450. The filtered signal from the BBF 312 may be upconverted via mixer 314 of the transmitter path 450. The upconverted signal from the mixer 314 may be amplified by the DA 316 (e.g., a first PA (PA1), also referred to as a preamplifier or pre-power amplifier (pre-PA)) of the transmitter path 450. The output voltage of DA 316 may be sent to an output of an LNA 324 of a receiver path 452 via a loopback voltage switch 406 of the loopback calibration path 408 to generate a loopback signal in the voltage domain. That is, the voltage from the DA 316 may be sent to the input of a transconductance (GM) amplifier 404 of the receiver path 452. The GM amplifier 404 then converts the voltage to a current, which is provided to a mixer 326 of the receiver path 452 for downconversion. The downconverted signal is then filtered via a BBF 328 of the receiver path 452, and the filtered signal may be converted from the analog domain to the digital domain via the ADC 330 of the receiver path 452. The analog signal from the ADC 330 is then processed by controller 402 for calibration as described herein. In other words, the calibration is performed based on a processed version of a signal received via the loopback calibration path.

The mixer 326, BBF 328, and ADC 330 shown in FIG. 4 may be implemented for each of an I path and Q path of the receiver (e.g., receiver path 452). The gain difference and the phase different between the I and Q paths may be calibrated as described herein.

Suppose the distance between the transmitter path and receiver path is long (e.g., which may be by design to reduce transmitter-to-receiver interference). In that case, the DA output voltage may be converted from the voltage domain to the current domain in the loopback calibration path to avoid issues with the voltage drop across the calibration path.

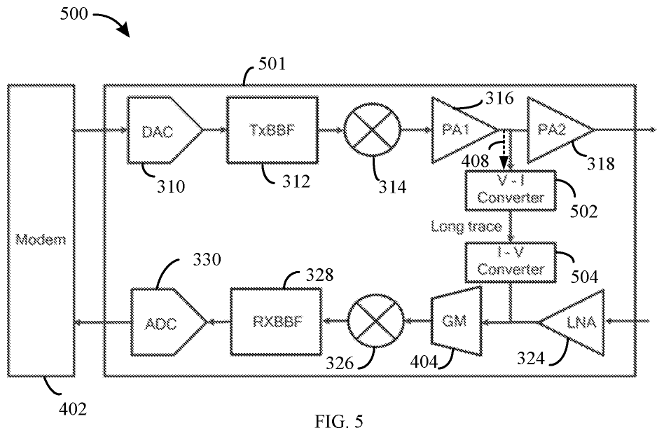

FIG. 5 is an example wireless device 500 with an RF transceiver circuit 501 including a loopback calibration path implemented with voltage-to-current and current-to-voltage converters, in accordance with certain aspects of the present disclosure. As shown, the loopback calibration path 408 may include a voltage-to-current (V-I) converter 502 converting the voltage at the output of the DA 316 to a current. The current flows across the long trace of the loopback calibration path between the transmitter and receiver. The loopback calibration path 408 may include a current-to-voltage (I-V) converter 504 to convert the current back to a voltage that is provided to the input of GM amplifier 404, as shown.

In both implementations described with respect to FIGS. 4 and 5, the voltage sent via the loopback calibration path 408 is provided to the output of the LNA (e.g., input of GM amplifier 404) and is processed through the GM amplifier 404, mixer 326, BBF 328, and ADC 330 to generate the transmitter to receiver loopback. Providing the loopback voltage to the output of the LNA 324 may impact the LNA frequency response and cause a gain or noise figure shift that can adversely impact the accuracy of the calibration. Moreover, using V-I and I-V converters as described with respect to FIG. 5 may cause process-voltage-temperature-dependent gain and phase variations, which can also reduce the calibration accuracy. While the LNA may be turned off (disabled) during calibration, when providing the voltage to the output of the LNA, the LNA 324 may be used as a load to draw current from the I-V converter 504, causing increased current consumption. Certain aspects of the present disclosure are directed towards a loopback calibration path that is coupled between the output of the DA 316 and an output of the GM amplifier, reducing current consumption and increasing calibration accuracy.

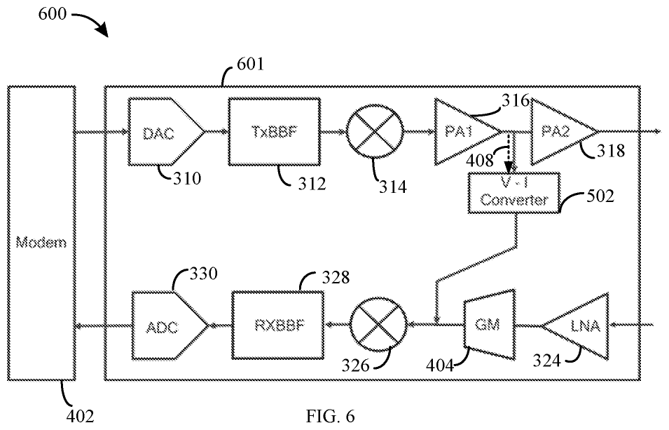

FIG. 6 is an example wireless device 600 with an RF transceiver circuit 601 including a loopback calibration path between an output of DA 316 and output of GM amplifier 404, in accordance with certain aspects of the present disclosure. As shown, the loopback calibration path 408 may include the V-I converter 502 to convert the voltage from the DA 316 to a current provided to the output of the GM amplifier 404, but lacks the I-V converter 504. That is, the voltage from DA 316 is delivered to the loopback V-I converter 502, converted from the voltage domain to the current domain, and delivered to the receiver GM amplifier output. Then, voltage from the DA 316 as converted to the current domain is then processed through the mixer 326 and BBF 328, and provided to ADC 330.

By not using the I-V converter 504 described with respect to FIG. 5, the process-voltage-temperature-dependent gain and phase variations caused by the loopback calibration path (e.g., caused by the I-V converter 504) are reduced, increasing the calibration accuracy. Moreover, by coupling the loopback calibration path to the output of the GM amplifier 404 (e.g., instead of the output of the LNA 324), the LNA may be disabled and not used as a load, reducing the current consumption during calibration.

Due to the loopback calibration path being coupled to the output of the GM amplifier 404, the loopback path may not cause loading of the LNA 324 during receive mode, reducing process-voltage-temperature-dependent variations of LNA frequency selectivity, gain, and noise figure. Moreover, the loopback calibration path may not use the GM amplifier as a calibration path. Thus, the GM amplifier may be turned off completely, reducing process-voltage-temperature-dependent gain and phase variations caused by the GM amplifier and increasing the calibration accuracy. With the GM amplifier being turned off, the current consumption that would otherwise be consumed by the GM amplifier 404 is saved, reducing calibration power consumption.

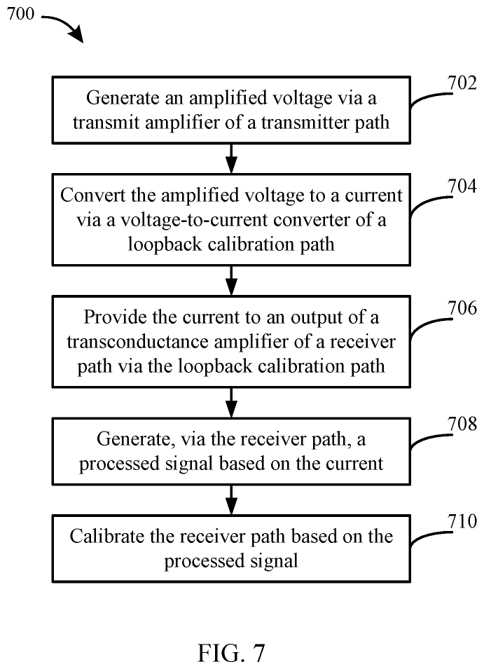

FIG. 7 is a flow diagram illustrating example operations 700 for wireless communication, in accordance with certain aspects of the present disclosure. The operations 700 may be performed, for example, a wireless device, such as the wireless device 600.

At block 702, the wireless device generates an amplified voltage via a transmit amplifier (e.g., DA 316 of FIG. 6, which may also be referred to as a pre-PA) of a transmitter path (e.g., transmitter path 450).

At block 704, the wireless device converts the amplified voltage to a current via a voltage-to-current converter (e.g., V-I converter 502) of a loopback calibration path (e.g., loopback calibration path 408). At block 706, the wireless device provides the current to an output of a transconductance amplifier (e.g., GM amplifier 404) of a receiver path (e.g., receiver path 452) via the loopback calibration path. At block 708, the wireless device generates, via the receiver path, a processed signal based on the current.

At block 710, the wireless device calibrates (e.g., via controller 402) the receiver path based on the processed signal. In some aspects, the wireless device may turn off the transconductance amplifier during loopback calibration of the receiver path. The receiver path may also include a receiver amplifier (e.g., LNA 324). The wireless device may turn off the receiver amplifier during loopback calibration. Calibrating the receiver path at block 710 may include at least one of: reducing (e.g., minimizing) a gain difference between an in-phase (I) path and a quadrature (Q) path of the receiver path; or setting (e.g., adjusting) a phase difference between an I path and Q path of the receiver path to be 90°. The mixer 326, BBF 328, and ADC 330 shown in FIG. 6 may be implemented for each of an I path and Q path of the receiver (e.g., receiver path). The gain difference and the phase different between the I and Q paths may be calibrated as described.

The wireless device may generate an upconverted signal via a transmit mixer (e.g., mixer 314) of the transmitter path. The amplified voltage may be generated based on the upconverted signal. The wireless device may generate the processed signal by generating, via a receive mixer (e.g., mixer 326), a downconverted signal based on the current from the loopback calibration path. The wireless device may generate, via a filter (e.g., BBF 328), a filtered signal based on the downconverted signal, and generate, via an analog-to-digital converter (e.g., ADC 330), a digital signal based on the filtered signal. The receiver path may be calibrated based on the digital signal.

### Example Aspects

In addition to the various aspects described above, specific combinations of aspects are within the scope of the disclosure, some of which are detailed below:

Aspect 1: An apparatus for wireless communication, comprising: a transmitter path including a first transmit amplifier; a receiver path including a transconductance amplifier; and a loopback calibration path coupled between an output of the first transmit amplifier and an output of the transconductance amplifier, wherein the loopback calibration path comprises a voltage-to-current converter.

Aspect 2: The apparatus of Aspect 1, wherein the transconductance amplifier is configured to be off during calibration of the receiver path using the loopback calibration path.

Aspect 3: The apparatus of Aspect 1 or 2, wherein the receiver path further comprises a receiver amplifier including an output coupled to an input of the transconductance amplifier, the receiver amplifier being configured to be off during calibration of the receiver path using the loopback calibration path.

Aspect 4: The apparatus of Aspect 3, wherein the receiver amplifier comprises a low noise amplifier (LNA).

Aspect 5: The apparatus according to any of Aspects 1-4, wherein the transmitter path comprises a second transmit amplifier including an input coupled to an output of the first transmit amplifier.

Aspect 6: The apparatus of Aspect 5, wherein the first transmit amplifier comprises a driver amplifier (DA) and wherein the second transmit amplifier comprises a power amplifier (PA).

Aspect 7: The apparatus according to any of Aspects 1-6, wherein: the transmitter path comprises a transmit mixer including an output coupled to an input of the first transmit amplifier; and the receiver path comprises a receive mixer including an input coupled to the output of the transconductance amplifier.

Aspect 8: The apparatus according to any of Aspects 1-7, further comprising a controller coupled to the receiver path and configured to perform calibration for the receiver path based on a processed version of a signal received via the loopback calibration path.

Aspect 9: The apparatus of Aspect 8, wherein, to perform the calibration, the controller is configured to reduce a gain difference between an in-phase (I) path and a quadrature (Q) path of the receiver path.

Aspect 10: The apparatus of Aspect 8 or 9, wherein, to perform the calibration, the controller is configured to set a phase difference between an in-phase (I) path and a quadrature (Q) path of the receiver path to be 90°.

Aspect 11: A method for wireless communication, comprising: generating an amplified voltage via a transmit amplifier of a transmitter path; converting the amplified voltage to a current via a voltage-to-current converter of a loopback calibration path; providing the current to an output of a transconductance amplifier of a receiver path via the loopback calibration path; generating, via the receiver path, a processed signal based on the current; and calibrating the receiver path based on the processed signal.

Aspect 12: The method of Aspect 11, further comprising turning off the transconductance amplifier during calibration of the receiver path using the loopback calibration path.

Aspect 13: The method of Aspect 11 or 12, wherein the receiver path further comprises a receiver amplifier, the method further comprising turning off the receive amplifier during calibration of the receiver path using the loopback calibration path.

Aspect 14: The method of Aspect 13, wherein the receive amplifier comprises a low noise amplifier (LNA).

Aspect 15: The method according to any of Aspects 11-14, wherein the transmit amplifier comprises a pre-power amplifier (pre-PA).

Aspect 16: The method according to any of Aspects 11-15, wherein: the method further comprises generating an upconverted signal via a transmit mixer of the transmitter path, wherein the amplified voltage is generated based on the upconverted signal; generating the processed signal comprises generating, via a receive mixer, a downconverted signal based on the current from the loopback calibration path; generating, via a filter, a filtered signal based on the downconverted signal; and generating, via an analog-to-digital converter, a digital signal based on the filtered signal, wherein calibrating the receiver path comprises calibrating the receiver path based on the digital signal.

Aspect 17: The method according to any of Aspects 11-16, wherein calibrating the receiver path comprises reducing a gain difference between an in-phase (I) path and a quadrature (Q) path of the receiver path.

Aspect 18: The method according to any of Aspects 11-17, wherein calibrating the receiver path comprises setting a phase difference between an in-phase (I) path and a quadrature (Q) path of the receiver path to be 90°.

Aspect 19: A wireless device, comprising: at least one antenna; a transmitter path coupled to the at least one antenna and including a transmit amplifier; a receiver path coupled to the at least one antenna and including a transconductance amplifier; and a loopback calibration path coupled between an output of the transmit amplifier and an output of the transconductance amplifier, wherein the loopback calibration path comprises a voltage-to-current converter.

Aspect 20: The wireless device of Aspect 19, wherein the transconductance amplifier is configured to be off during calibration of the receiver path using the loopback calibration path.

### Additional Considerations

The various operations of methods described above may be performed by any suitable means capable of performing the corresponding functions. The means may include various hardware and/or software component(s) and/or module(s), including, but not limited to a circuit, an application-specific integrated circuit (ASIC), or a processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. An apparatus for wireless communication, comprising:
a transmitter path including a first transmit amplifier;
a receiver path including a transconductance amplifier; and
a loopback calibration path coupled between an output of the first transmit amplifier and an output of the transconductance amplifier, wherein the loopback calibration path comprises a voltage-to-current converter.

2. The apparatus of claim 1, wherein the transconductance amplifier is configured to be off during calibration of the receiver path using the loopback calibration path.

3. The apparatus of claim 1, wherein the receiver path further comprises a receiver amplifier including an output coupled to an input of the transconductance amplifier, the receiver amplifier being configured to be off during calibration of the receiver path using the loopback calibration path.

4. The apparatus of claim 3, wherein the receiver amplifier comprises a low noise amplifier (LNA).

5. The apparatus of claim 1, wherein the transmitter path comprises a second transmit amplifier including an input coupled to an output of the first transmit amplifier.

6. The apparatus of claim 5, wherein the first transmit amplifier comprises a driver amplifier (DA) and wherein the second transmit amplifier comprises a power amplifier (PA).

7. The apparatus of claim 1, wherein:
the transmitter path comprises a transmit mixer including an output coupled to an input of the first transmit amplifier; and
the receiver path comprises a receive mixer including an input coupled to the output of the transconductance amplifier.

8. The apparatus of claim 1, further comprising a controller coupled to the receiver path and configured to perform calibration for the receiver path based on a processed version of a signal received via the loopback calibration path.

9. The apparatus of claim 8, wherein, to perform the calibration, the controller is configured to reduce a gain difference between an in-phase (I) path and a quadrature (Q) path of the receiver path.

10. The apparatus of claim 8, wherein, to perform the calibration, the controller is configured to set a phase difference between an in-phase (I) path and a quadrature (Q) path of the receiver path to be 90°.

11. A method for wireless communication, comprising:
generating an amplified voltage via a transmit amplifier of a transmitter path;
converting the amplified voltage to a current via a voltage-to-current converter of a loopback calibration path;
providing the current to an output of a transconductance amplifier of a receiver path via the loopback calibration path;
generating, via the receiver path, a processed signal based on the current; and
calibrating the receiver path based on the processed signal.

12. The method of claim 11, further comprising turning off the transconductance amplifier during calibration of the receiver path using the loopback calibration path.

13. The method of claim 11, wherein the receiver path further comprises a receiver amplifier, the method further comprising turning off the receive amplifier during calibration of the receiver path using the loopback calibration path.

14. The method of claim 13, wherein the receive amplifier comprises a low noise amplifier (LNA).

15. The method of claim 11, wherein the transmit amplifier comprises a pre-power amplifier (pre-PA).

16. The method of claim 11, wherein:
the method further comprises generating an upconverted signal via a transmit mixer of the transmitter path, wherein the amplified voltage is generated based on the upconverted signal;
generating the processed signal comprises generating, via a receive mixer, a downconverted signal based on the current from the loopback calibration path;
generating, via a filter, a filtered signal based on the downconverted signal; and
generating, via an analog-to-digital converter, a digital signal based on the filtered signal, wherein calibrating the receiver path comprises calibrating the receiver path based on the digital signal.

17. The method of claim 11, wherein calibrating the receiver path comprises reducing a gain difference between an in-phase (I) path and a quadrature (Q) path of the receiver path.

18. The method of claim 11, wherein calibrating the receiver path comprises setting a phase difference between an in-phase (I) path and a quadrature (Q) path of the receiver path to be 90°.

19. A wireless device, comprising:
at least one antenna;
a transmitter path coupled to the at least one antenna and including a transmit amplifier;
a receiver path coupled to the at least one antenna and including a transconductance amplifier; and
a loopback calibration path coupled between an output of the transmit amplifier and an output of the transconductance amplifier, wherein the loopback calibration path comprises a voltage-to-current converter.

20. The wireless device of claim 19, wherein the transconductance amplifier is configured to be off during calibration of the receiver path using the loopback calibration path.
